(19) United States
(12) Patent Application Publication
(10) Pub. No.: US 2021/0288255 A1
(43) Pub. Date: Sep. 16, 2021

(54) Method for Manufacturing Display Substrate, Display Substrate and Display Device

(71) Applicant: BOE Technology Group Co., Ltd., Beijing (CN)

(72) Inventors: Tun Liu, Beijing (CN); Zhiqiang JIAO, Beijing (CN)

(21) Appl. No.: 17/058,858

(22) PCT Filed: Apr. 9, 2020
(86) PCT No.: PCT/CN2020/083977

§ 371 Date: Nov. 25, 2020

(30) Foreign Application Priority Data
Jun. 25, 2019 (CN) 201910556437.6

(51) Int. Cl. H01L 51/00; H01L 51/56

(52) U.S. Cl. CPC H01L 51/0016; H01L 51/5088; H01L 51/56

(57) ABSTRACT

A method for manufacturing a display substrate, a display substrate and a display device are provided. The method includes: forming a pixel defining layer for defining a plurality of pixel regions on a base substrate; forming a photodegradable layer between adjacent pixel regions on a side of the pixel defining layer distal to the base substrate; forming an evaporated layer on the base substrate on which the photodegradable layer is formed; and irradiating the photodegradable layer with a photolysis light to decompose the photodegradable layer so that the evaporated layer is disconnected between adjacent pixel regions.

### CROSS-REFERENCE TO RELATED APPLICATION

The present application claims the benefit of Chinese Patent Application No. 201910556437.6 filed on Jun. 25, 2019 in the National Intellectual Property Administration of China, which is in entirety incorporated herein by reference.

### TECHNICAL FIELD

The present disclosure relates to the field of display technology, and in particular to a method for manufacturing a display substrate, a display substrate and a display device.

### BACKGROUND

Organic Light Emitting Diode (OLED) display panels have attracted the attention of the industry due to their characteristics such as self-luminescence, low driving voltage, fast response, and wide viewing angle. The OLED display panel includes a plurality of OLED devices defined by a pixel defining layer. The OLED device includes an anode, a hole injection layer, a hole transport layer, an organic light emitting layer, an electron transport layer, a cathode, and the like.

### SUMMARY

According to an aspect of the present disclosure, there is provided a method for manufacturing a display substrate, the method including: forming a pixel defining layer for defining a plurality of pixel regions on a base substrate; forming a photodegradable layer between adjacent pixel regions on a side of the pixel defining layer distal to the base substrate; forming an evaporated layer on the base substrate on which the photodegradable layer is formed; irradiating the photodegradable layer with a photolysis light to decompose the photodegradable layer so that the evaporated layer is disconnected between adjacent pixel regions.

In some embodiments, the evaporated layer is a hole injection layer.

In some embodiments, the evaporated layer forms a hollow region at the disconnected location, an orthographic projection of the hollow region on the base substrate and an orthographic projection of the photodegradable layer on the base substrate at least partially overlap with each other.

In some embodiments, material of the photodegradable layer includes a triazene polymer.

In some embodiments, the photodegradable layer has a thickness of 50 nm to 200 nm.

In some embodiments, a width of the photodegradable layer is smaller than a width of the pixel defining layer, between adjacent pixel regions.

In some embodiments, an orthographic projection of the photodegradable layer on the base substrate falls within an orthographic projection of the pixel defining layer on the base substrate.

In some embodiments, forming the photodegradable layer between adjacent pixel regions on the side of the pixel defining layer distal to the base substrate, includes: coating a photodegradable film on the base substrate on which the pixel defining layer is formed; exposing the photodegradable film by using a mask to a light, forming an unexposed region at position where a photodegradable layer is located, and forming an exposed region at other positions; developing the photodegradable film so that the photodegradable film is absent in the exposed region and the photodegradable film in the unexposed region is remained to form the photodegradable layer.

In some embodiments, a wavelength of the light for exposing the photodegradable film is less than 400 nm.

In some embodiments, a wavelength of the photolysis light is greater than 400 nm.

In some embodiments, the photolysis light includes pulsed laser or light wave.

In some embodiments, the pulsed laser has a wavelength of 500 nm to 550 nm.

In some embodiments, the method further includes:

before forming the pixel defining layer, forming an anode layer on the base substrate.

In some embodiments, the method, further includes: forming a cathode layer on a side of the hole injection layer with disconnection distal to the base substrate.

An embodiment of the present disclosure also provides a display substrate, including a base substrate and a pixel defining layer arranged on the base substrate for defining a plurality of pixel regions, the display substrate further including a hole injection layer, the hole injection layer being disconnected between adjacent pixel regions.

An embodiment of the present disclosure also provides a display substrate manufactured by the method described in any one of the above embodiments.

An embodiment of the present disclosure also provides a display device including the display substrate described in any one of the above embodiments.

Other features and advantages of the present disclosure will be described in the following specification, and partly become obvious from the specification, or understood by implementing the present disclosure. The objectives and other advantages of the present disclosure can be realized and obtained through the structures specifically pointed out in the specification, claims and drawings.

### BRIEF DESCRIPTION OF THE DRAWINGS

The accompanying drawings are used to provide a further understanding of the technical solution of the present disclosure, and constitute a part of the specification.

Together with the embodiments of the present application, they are used to explain the technical solution of the present disclosure, and do not constitute a limitation to the technical solution of the present disclosure.

FIG. 1A is a schematic flowchart of a method for manufacturing a display substrate according to an embodiment of the present disclosure;

FIG. 1B is an exemplary flowchart of the specific steps of step S2 in FIG. 1A;

FIG. 2 is a schematic diagram of the structure after forming a pixel defining layer in the display substrate;

FIG. 3A is a schematic diagram showing the exposure of the photodegradable film in the display substrate;

FIG. 3B is a schematic diagram showing the structure after the photodegradable layer is formed in the display substrate;

FIG. 3C is a top schematic diagram showing the structure after the photodegradable layer is formed in the display substrate;

FIG. 4 is a schematic diagram showing the structure after forming a hole injection layer in the display substrate;

FIG. 5A is a schematic diagram showing the irradiation of the photodegradable layer in the display substrate;

FIG. 5B is a schematic diagram showing the structure of the photodegradable layer in the display substrate after photolysis; and

FIG. 5C is a schematic diagram of forming a second electrode on the structure of the photodegradable layer in the display substrate after photolysis.

### DETAILED DESCRIPTION OF EMBODIMENTS

In order to make the objectives, technical solutions, and advantages of the present disclosure clearer, the embodiments of the present disclosure will be described in detail below with reference to the accompanying drawings. It should be noted that the embodiments in the application and the features in the embodiments can be combined with each other arbitrarily if there is no conflict.

In the manufacturing process of the display panel, an evaporation method can be used to form the OLED device. In order to achieve cost control and efficient production, a fine metal mask is generally not used for vapor deposition when forming a hole injection layer, but a large-aperture mask that can cover an active area is used for vapor deposition to form a common layer for sub-pixels, that is, the hole injection layer of multiple OLED pixels is an integral structure connected to each other. However, the inventor has discovered in use that, the OLED display panel manufactured in this way will cause pixel crosstalk during the working process. For example, when a certain pixel characteristic is displayed, one or more pixels around the certain pixel will also be bright. The crosstalk among pixels is generated, which adversely affects the display quality of the display panel.

Through research, the inventor has found that the hole injection layer as a common layer has higher electrical conductivity, and the carrier lateral transport rate in the hole injection layer is higher. Therefore, in a high-resolution display panel, when a certain pixel characteristic is displayed, the hole carrier concentration in the pixel region is relatively high. Therefore, the hole carriers in the pixel region will be transported laterally along the hole injection layer to other surrounding pixels such that one or more surrounding pixels are also bright. It causes defects of crosstalk among pixels, which adversely affects the display quality of the display device.

The embodiment of the present disclosure provides a method for manufacturing a display substrate. The method includes: forming a pixel defining layer for defining a plurality of pixel regions on a base substrate; forming a photodegradable layer located between adjacent pixel regions on a side of the pixel defining layer distal to the base substrate; forming an evaporated layer (such as a hole injection layer) on the base substrate on which the photodegradable layer is formed; irradiating the photodegradable layer with photolytic light to decompose the photodegradable layer so that the evaporated layer is broken between adjacent pixel regions. Here, the “evaporated layer” refers to a layer formed by an evaporation process, and may include, for example, a hole injection layer.

The technical content of the present disclosure will be described in detail below through specific embodiments. The coating can be done by using a known coating process, which is not specifically limited here.

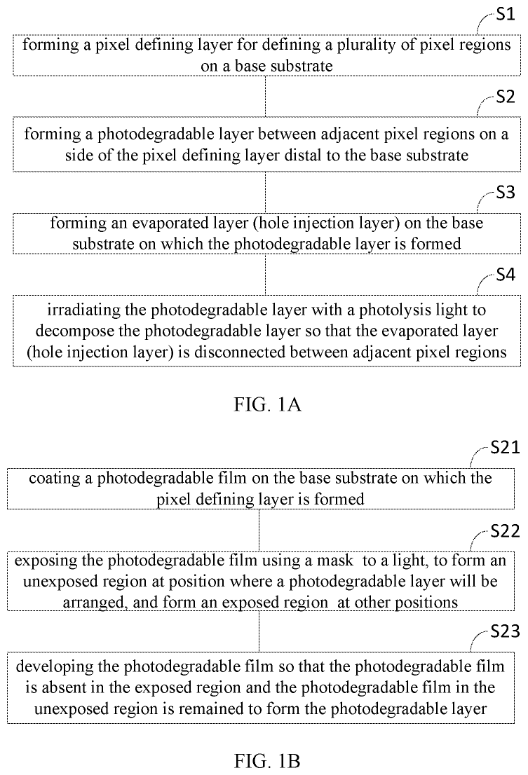

FIG. 1A is a schematic diagram of a manufacturing method of a display substrate according to an embodiment of the present disclosure. As shown in FIG. 1A, the method includes:

Step S1: forming a pixel defining layer for defining a plurality of pixel regions on the base substrate;

Step S2: forming a photodegradable layer located between adjacent pixel regions on a side of the pixel defining layer distal to the base substrate;

Step S3: forming an evaporated layer (such as a hole injection layer) on the base substrate on which the photodegradable layer is formed;

Step S4: irradiating the photodegradable layer with photolysis light to decompose the photodegradable layer so that the evaporated layer (for example, the hole injection layer) is disconnected between adjacent pixel regions.

In some embodiments, as shown in FIG. 1B, the step S2 may include:

Step S21: coating a photodegradable film on the base substrate on which the pixel defining layer is formed;

Step S22: exposing the photodegradable film using a mask (such as a monotone mask) to a light, to form an unexposed region at position where a photodegradable layer will be arranged, and form an exposed region (such as a fully exposed region) at other positions;

Step S23: developing the photodegradable film so that the photodegradable film is absent in the exposed region and the photodegradable film in the unexposed region is remained to form the photodegradable layer.

In some embodiments, the wavelength of light for exposing the photodegradable film to the light is less than a certain threshold (for example, less than 400 nm). The wavelength of light below this threshold can prevent the photodegradable film from being decomposed and removed.

The technical solutions of the embodiments of the present disclosure are described in detail below by the manufacturing process of the display substrate.

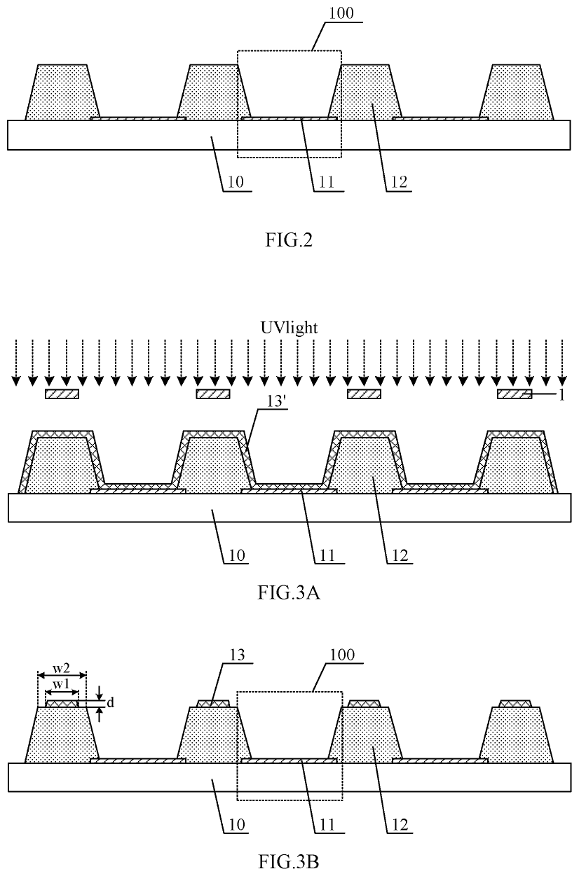

For step S1: forming a pixel defining layer for defining a plurality of pixel regions on a base substrate may specifically include: coating a pixel defining film on the base substrate 10; using a monotone mask to expose the pixel defining film to the light, forming an exposed region in the pixel regions, and forming an unexposed at other positions; after development, the pixel defining film is absent in the pixel regions, and the pixel defining film is maintained in the unexposed region to form a pixel defining layer 12. The pixel defining layer 12 defines a plurality of pixel regions 100, as shown in FIG. 2. FIG. 2 is a schematic diagram of the structure after forming a pixel defining layer on the display substrate.

It is understood that, before forming the pixel defining layer 11, the first electrode 11 is formed on the base substrate 10, and the first electrode 11 is located in the pixel region 100, as shown in FIG. 2. In the OLED display substrate, the first electrode 11 is usually an anode.

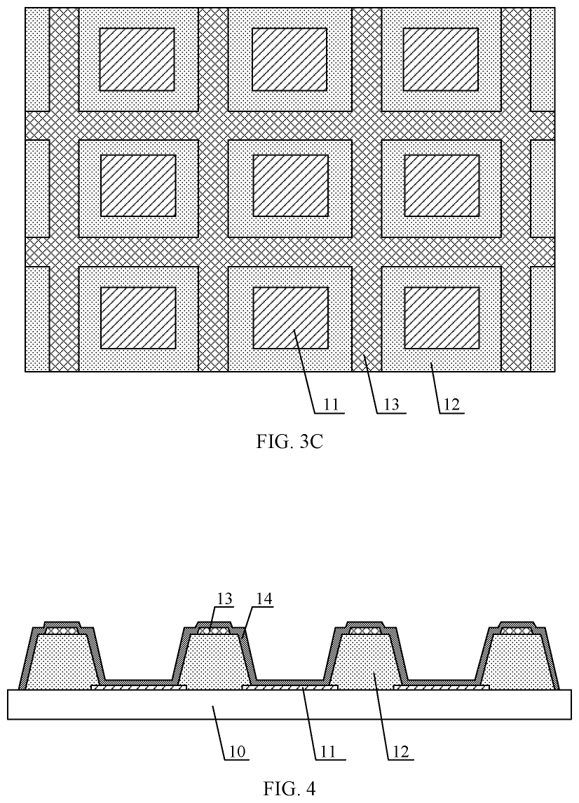

For step S2: forming a photodegradable layer 13 between adjacent pixel regions 100 on the side of the pixel defining layer 12 distal to the base substrate 10, specifically includes: coating the base substrate 10 on which the pixel defining layer 12 is formed with a photodegradable film 13′; using a monotone mask 1 to expose the photodegradable film 13′ to the light to form an unexposed region at the position where the photodegradable layer is located, and to form a fully exposed region at other positions, as shown in FIG. 3A; after development, the photodegradable film in the unexposed region is remained to form the photodegradable layer 13, and the exposed region has no photodegradable film and thus exposes the pixel region to the light, as shown in FIG. 3B. FIG. 3A is a schematic diagram showing the exposure of the photodegradable film in the display substrate to the light; FIG. 3B is a schematic diagram showing the structure after the photodegradable layer is formed in the display substrate.

In some embodiments, the photodegradable film includes a photodegradable substance and a resin. The photodegradable substance includes triazene polymers, and the resin includes diaminodiphenyl compounds and diamines with a high degree of conjugation. Diaminodiphenyl compounds and diamines are used as reaction substrates, and the photodegradable substance such as triazene polymer is dissolved in the reaction substrate formed by diaminodiphenyl compounds and diamines to obtain a photodegradable gel-like substance. The obtained photodegradable gel-like substance is coated on the base substrate 10 on which the pixel defining layer 12 is formed to form a photodegradable film. It is understood that other gel-like substances can also be selected to form the reaction substrate.

In some embodiments, the photodegradable substance can be rapidly photodegraded under light irradiation with wavelength not less than 400 nm. In order to prevent the exposure light from affecting the photodegradable layer, the exposure light used for exposing the photodegradable film 13′ is ultraviolet light with a wavelength less than 400 nm. The photodegradable substance will be photodegraded only under the irradiation of light with a wavelength not less than 400 nm, thus, in the process of exposing the photodegradable film to the light, the exposure light will not cause the photodegradable film to be decomposed, and the exposure light will not affect the photodegradable film.

As shown in FIG. 3B, between adjacent pixel regions 100, the width w1 of the photodegradable layer 13 is less than the width w2 of the pixel defining layer 12. The thickness d of the photodegradable layer 13 is 50 nm˜200 nm.

FIG. 3C is a top schematic diagram showing the structure after the photodegradable layer is formed in the display substrate. As shown in FIG. 3C, the photodegradable layer 13 is provided between adjacent pixel regions, so that viewed from the top view of the display substrate, the photodegradable layer 13 has a mesh structure, and the pixel regions are exposed through the hollows in the photodegradable layer 13.

For step S3: forming a hole injection layer on the base substrate on which the photodegradable layer 13 is formed, specifically includes: forming the hole injection layer 14 with an evaporation method, as shown in FIG. 4, which is a schematic diagram showing the structure after forming a hole injection layer in the display substrate.

For step S4: irradiating the photodegradable layer with photolysis light to decompose the photodegradable layer 13 so that the hole injection layer 14 forms hollow regions 15 at the positions corresponding to the photodegradable layer 13, that is, the hole injection layer 14 is disconnected. An example is given as follow.

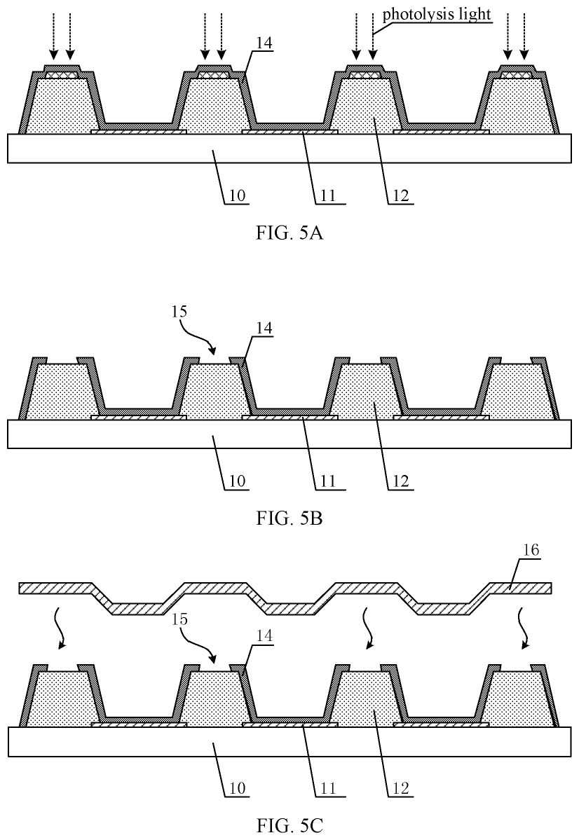

A photolysis light is used to irradiate the photodegradable layer 13, as shown in FIG. 5A, which is a schematic diagram showing the irradiation of the photodegradable layer in the display substrate. In one embodiment, the wavelength of the photolysis light is greater than 400 nm. The photolysis light may include pulsed laser or light waves with a wavelength greater than 400 nm. For example, the wavelength of the pulsed laser is between 500 nm and 560 nm. By reasonably controlling the pulse width, frequency and energy (<3 mJ) of the pulsed laser, the laser damage threshold can be controlled within a range of equal to or less than 20 mJ/cm². It will not damage other layers when the pulsed laser irradiates the photodegradable layer. It is possible to prevent the light wave from causing damage to other layers, by reasonably controlling the irradiation energy of the light wave, when the photolysis light is a light wave with a wavelength greater than 400 nm. During the process of the photolysis light irradiating the position corresponding to the photodegradable layer 13, since the energy of the photolysis light is low, the photolysis light will not cause an ablation to other film layers, and will not affect the performance of the OLED device.

In the above-mentioned embodiment, the hole injection layer 14 forms a hollow region 15 at the disconnection position. The orthographic projection of the hollow region 15 on the base substrate 10 and the orthographic projection of the photodegradable layer 13 on the base substrate 10 are at least partially overlapped. The hollow region 15 is formed by photolysis of the photodegradable layer 13.

In some embodiments, in order to prevent the photolysis light from irradiating the region out of the photolysis layer, a shield can be provided on the hole injection layer, and the shield has an opening corresponding to the position of the photolysis layer, and the photolysis light passes through the hollow region and irradiates on the position corresponding to the photodegradable layer.

When the photolysis light is used to irradiate the position corresponding to the photodegradable layer 13, the photodegradable layer 13 will absorb the photolysis light to cause photolysis. The shock wave released by the photodegradable layer 13 during the photolysis process will push the hole injection layer 14 covering the photodegradable layer away, so that the hole injection layer 14 forms a hollow region 15 and is disconnected at a position corresponding to the photodegradable layer. As shown in FIG. 5B, which is a schematic diagram showing the structure of the photodegradable layer in the display substrate after photolysis, and there is no residue after photolysis of the photodegradable layer. The hollow region 15 blocks the lateral transport of carriers in the hole injection layer, avoiding crosstalk between pixels and improving the display quality of the display panel.

In the method for manufacturing the display substrate provided by the embodiment of the present disclosure, the hole injection layer is disconnected at a position corresponding to the photodegradable layer, and the disconnection position is located between adjacent pixel regions, so that the disconnection can block the lateral transport of the carriers in the hole injection layer, avoiding the crosstalk between pixels and improving the display quality of the display device.

In order to make the shock wave released during the photolysis of the photodegradable layer 13 completely remove the hole injection layer 14 covering the photodegradable layer, as shown in FIG. 3B, the thickness d of the photodegradable layer 13 may be, for example, 50 nm to 200 nm. The photodegradable layer 13 having this thickness can generate a shock wave with sufficient energy during the photolysis process, so as to completely move the hole injection layer 14 covering the photodegradable layer away. In addition, the photodegradable layer 13 with this thickness will not affect the film layer to be formed subsequently.

In order to prevent the hollow region 15 from being formed in the pixel region, as shown in FIG. 3B, the width w1 of the photodegradable layer 13 is smaller than the width w2 of the pixel defining layer 12, between adjacent pixel regions 100. Therefore, the formed disconnection 15 will not affect the pixel region, and will not affect the preparation and performance of the subsequent film layers. In some embodiments, the orthographic projection of the photodegradable layer 13 on the base substrate 10 falls within the orthographic projection of the pixel defining layer 12 on the base substrate 10. In other words, the pixel defining layer 12 can completely cover the photodegradable layer 13, so as to prevent the photodegradable layer 13 from being provided in the opening region of the pixel defining layer 12, so as to avoid adversely affecting the preparation and performance of subsequent film layers.

During the process of the photolysis light irradiating the photodegradable layer 13, since the energy of the photolysis light is low, the photolysis light will not ablate other film layers and will not adversely affect the performance of the OLED device.

In some embodiments, the display substrate is an OLED display substrate. After the hole injection layer forms the hollow region 15 and is disconnected, the method for manufacturing the display substrate may further include: sequentially forming a hole transport layer, an organic light-emitting layer, an electron transport layer, an electron injection layer and the second electrode on the hole injection layer. The organic light-emitting layer is arranged in the OLED pixel region. The hole transport layer, the electron transport layer, the electron injection layer and the second electrode are all connected to each other in an integrated structure. The second electrode may be the cathode of the OLED device.

In some embodiments, as shown in FIG. 5C, after the hole injection layer forms the hollow region 15 and is disconnected, the second electrode 16 is formed on the side of the hole injection layer distal to the base substrate, thereby avoiding influence of the photolysis process of the photodegradable layer on the second electrode, ensuring the performance of the second electrode. The curved arrow under the second electrode 16 in FIG. 5C indicates that the second electrode 16 will be formed on the side of the hole injection layer 14 distal to the base substrate 10.

It is understood that, in other embodiments, after the hole transport layer is formed, photolysis light may be used to irradiate the photodegradable layer so that the hole injection layer forms a disconnection at a position corresponding to the photodegradable layer, or after the organic light-emitting layer is formed, the photodegradable layer can be irradiated with photolysis light so that the hole injection layer forms a disconnection at the position corresponding to the photodegradable layer; or, after the electron transport layer or the electron injection layer is formed, the photolysis light is used to irradiate the photolysis layer so that the hole injection layer forms disconnection at the position corresponding to the photolysis layer.

Although the hole injection layer has been described as an example of the evaporated layer in the above embodiments, the embodiments of the present disclosure are not limited to this, and the evaporated layer may also be any of other structural layers, such as a hole transport layer.

The embodiment of the present disclosure also proposes a display substrate, which is prepared by the manufacturing method of above-mentioned embodiment. The display substrate, as shown in FIG. 5B, includes a base substrate 10 and a pixel defining layer 12 arranged on the base substrate 10 for defining a plurality of pixel regions. The display substrate further includes a hole injection layer 14 disposed on the pixel defining layer 12, and the hole injection layer 14 is disconnected (with hollow regions 15) between adjacent pixel regions.

The embodiments of the present disclosure also provide a display device, which includes the display substrate adopting the foregoing embodiments. The display device can be any products or components with a display function, such as a mobile phone, a tablet computer, a television, a monitor, a notebook computer, a digital photo frame, a navigator.

In the description of the embodiments of the present disclosure, it should be understood that, the orientation or positional relationship indicated by the terms “middle”, “upper”, “lower”, “front”, “rear”, “vertical”, “horizontal”, “top”, “bottom”, “inner”, “outer” is based on the orientation or positional relationship shown in the drawings, and is only for the convenience of describing the present disclosure and simplifying the description, instead of indicating or implying the pointed device or element must have a specific orientation, be constructed and operated in a specific orientation, and therefore cannot be understood as a limitation to the present disclosure.

In the description of the embodiments of the present disclosure, it should be noted that, unless otherwise clearly specified and limited, the terms “installation”, “connection”, and “connections” should be construed broadly, for example, they may be fixed connection or removable connection, or integral connection; it can be mechanical connection or electrical connection; it can be directly connected or indirectly connected through an intermediate medium, and it can be the internal communication between two components. For those of ordinary skill in the art, the specific meaning of the above-mentioned terms in the present disclosure can be understood in specific situations.

Although the embodiments disclosed in the present disclosure are as described above, the content described is only the embodiments used to facilitate the understanding of the present disclosure, and is not intended to limit the present disclosure. Anyone skilled in the art to which this disclosure belongs, without departing from the spirit and scope disclosed in this disclosure, can make any modifications and changes in the implementation form and details, but the scope of patent protection of this disclosure should still be defined by the appended claims.

1. A method for manufacturing a display substrate, the method comprising:
forming a pixel defining layer for defining a plurality of pixel regions on a base substrate;
forming a photodegradable layer between adjacent pixel regions on a side of the pixel defining layer distal to the base substrate;
forming an evaporated layer on the base substrate on which the photodegradable layer is formed; and
irradiating the photodegradable layer with a photolysis light to decompose the photodegradable layer so that the evaporated layer is disconnected between adjacent pixel regions.

2. The method according to claim 1, wherein the evaporated layer is a hole injection layer.

3. The method according to claim 1, wherein the evaporated layer forms a hollow region at the disconnected location, an orthographic projection of the hollow region on the base substrate and an orthographic projection of the photodegradable layer on the base substrate at least partially overlap with each other.

4. The method according to claim 1, wherein material of the photodegradable layer comprises a triazene polymer.

5. The method according to claim 1, wherein the photodegradable layer has a thickness of 50 nm to 200 nm.

6. The method according to claim 1, wherein a width of the photodegradable layer is smaller than a width of the pixel defining layer, between adjacent pixel regions.

7. The method according to claim 1, wherein an orthographic projection of the photodegradable layer on the base substrate falls within an orthographic projection of the pixel defining layer on the base substrate.

8. The method according to claim 1, wherein forming the photodegradable layer between adjacent pixel regions on the side of the pixel defining layer distal to the base substrate, comprises:
coating a photodegradable film on the base substrate on which the pixel defining layer is formed;
exposing the photodegradable film by using a mask to a light, forming an unexposed region at position where a photodegradable layer is located, and forming an exposed region at other positions;
developing the photodegradable film so that the photodegradable film is absent in the exposed region and the photodegradable film in the unexposed region is remained to form the photodegradable layer.

9. The method according to claim 8, wherein a wavelength of the light for exposing the photodegradable film is less than 400 nm.

10. The method according to claim 1, wherein a wavelength of the photolysis light is greater than 400 nm.

11. The method according to claim 10, wherein the photolysis light comprises pulsed laser or light wave.

12. The method according to claim 11, wherein the pulsed laser has a wavelength of 500 nm to 550 nm.

13. The method according to claim 1, further comprising:
before forming the pixel defining layer, forming an anode layer on the base substrate.

14. The method according to claim 1, further comprising: forming a cathode layer on a side of the hole injection layer with disconnection distal to the base substrate.

15. A display substrate, comprising a base substrate and a pixel defining layer arranged on the base substrate for defining a plurality of pixel regions, the display substrate further comprising a hole injection layer, the hole injection layer being disconnected between adjacent pixel regions.

16. A display substrate manufactured by the method according to claim 1.

17. A display device comprising the display substrate according to claim 15.

18. The method according to claim 2, wherein the evaporated layer forms a hollow region at the disconnected location, an orthographic projection of the hollow region on the base substrate and an orthographic projection of the photodegradable layer on the base substrate at least partially overlap with each other.

19. The method according to claim 2, wherein a width of the photodegradable layer is smaller than a width of the pixel defining layer, between adjacent pixel regions.

20. The method according to claim 2, wherein an orthographic projection of the photodegradable layer on the base substrate falls within an orthographic projection of the pixel defining layer on the base substrate.
